(19) United States
(12) Patent Application Publication
(10) Pub. No.: US 2021/0277173 A1
(43) Pub. Date: Sep. 9, 2021

(54) PHOTOSENSITIVE EPOXY RESIN COMPOSITION FOR FORMATION OF OPTICAL WAVEGUIDE, PHOTOSENSITIVE FILM FOR FORMATION OF OPTICAL WAVEGUIDE, OPTICAL WAVEGUIDE PRODUCED BY USING THE PHOTOSENSITIVE EPOXY RESIN COMPOSITION OR THE PHOTOSENSITIVE FILM, AND HYBRID FLEXIBLE PRINTED WIRING BOARD FOR OPTICAL AND ELECTRICAL TRANSMISSION

(71) Applicant: NITTO DENKO CORPORATION, Ibaraki-shi, Osaka (JP)

(72) Inventors: Kazuaki Suzuki, Ibaraki-shi (JP); Shinya Ota, Ibaraki-shi (JP)

(73) Assignee: NITTO DENKO CORPORATION, Ibaraki-shi, Osaka (JP)

(21) Appl. No.: 17/261,769

(22) PCT Filed: Jul. 26, 2019
(86) PCT No.: PCT/JP2019/029380

§ 371 Date: Jan. 20, 2021

(30) Foreign Application Priority Data
Jul. 31, 2018 (JP) 2018-143495

(51) Int. Cl. C08G 59/38; C08G 59/32; G02B 6/122; H05K 1/03; H05K 1/02

(52) U.S. Cl. CPC C08G 59/38; C08G 59/3218; G02B 2006/12073; H05K 1/0326; H05K 1/0274; G02B 6/1221

(57) ABSTRACT

A photosensitive epoxy resin composition for formation of an optical waveguide, which can be used as an optical waveguide forming material excellent in thermal coloration resistance, patternability, and R-to-R adaptability (flexibility in an uncured resin state). The photosensitive epoxy resin composition contains an epoxy resin component and a photo-cationic polymerization initiator, wherein the epoxy resin component comprises an epoxy resin having a tri- or higher functional bisphenol-A skeleton.

### TECHNICAL FIELD

The present disclosure relates to a photosensitive epoxy resin composition for forming an optical wavelength and a photosensitive film for forming an optical waveguide, to be used as materials for the formation of a cladding layer, a core layer or the like constituting an optical waveguide in an optical and electrical transmission hybrid flexible printed wiring board which is widely used for optical communications, optical information processing, and other general optics. The present disclosure further relates to an optical waveguide produced by using the photosensitive resin composition or the photosensitive film, and to a hybrid flexible printed wiring board for optical and electrical transmission.

### BACKGROUND ART

Conventionally, various photosensitive epoxy resin compositions are used as optical waveguide forming materials (so-called cladding layer forming materials, core layer forming materials, and the like) for hybrid flexible printed wiring boards for optical and electrical transmission. Where a cladding layer or a core layer is formed in a predetermined pattern by using any of the photosensitive epoxy resin compositions, for example, the formation of the predetermined cladding layer pattern or core layer pattern is achieved by irradiation with ultraviolet (UV) radiation via a photomask. More specifically, the cladding layer or the core layer is formed by using a liquid photosensitive epoxy resin composition as an optical waveguide forming material to form a film (layer) and then irradiating the film (layer) with UV radiation via the photomask.

Such a photosensitive epoxy resin composition has high photocurability, but is disadvantageous in that the photosensitive epoxy resin composition cannot be employed for a continuous process such as an R-to-R (roll-to-roll) process because of the surface tackiness of a coating film of the photosensitive epoxy resin composition (i.e., the film of the photosensitive epoxy resin composition is liable to be broken when being brought into contact with a roll) and, hence, has lower productivity (PTL 1). Therefore, a resin component that is solid at an ordinary temperature is generally used as a photosensitive resin for R-to-R process adaptability. As the molecular weight of the photosensitive resin increases, the flexibility of an uncured amorphous film of the resin composition is increased, but the patterning resolution is reduced. As the molecular weight of the photosensitive resin decreases, on the other hand, the patterning resolution is increased, but the flexibility is reduced. In general, there is a trade-off relationship between the flexibility and the patterning resolution of the film, which is a problem. Therefore, there is a demand for an optical waveguide forming material which satisfies the requirements for both the flexibility and the patterning resolution of the film. For example, a resin composition containing epoxy-containing acryl rubber, urethane (meth)acrylate or (meth)acrylate free from a urethane bond has been proposed as a cladding layer forming material for an optical waveguide (PTL 2).

In recent years, optical waveguides are used in a wide variety of environments for information communications at increasingly higher speeds with increasingly higher capacities. It is expected that the optical waveguides will be used in higher temperature environments. Since such an optical waveguide is used in combination with an electric wiring board, an optical fiber or the like, the optical waveguide is exposed to a high temperature in an IC element mounting process and a connector connecting process. Therefore, photosensitive epoxy resin compositions having higher heat resistance have been developed, which are prepared by blending various resins with a specific novolak type polyfunctional epoxy resin as a main component (PTL 3). In order to ensure a lower propagation loss of the optical waveguide during information transmission through the optical waveguide in the wide variety of environments, material design less susceptible to thermal coloration is required.

Therefore, an optical waveguide forming material which is excellent in thermal coloration resistance and patternability, and is highly flexible in an uncured resin state in the R-to-R process is desired for the optical waveguide.

### RELATED ART DOCUMENTS

### Patent Documents

PTL 1: JP-A-2001-281475

PTL 2: JP-A-2011-27903

PTL 3: JP-A-2014-215531

### SUMMARY

In view of the foregoing, the present disclosure provides an optical waveguide formation photosensitive epoxy resin composition and an optical waveguide formation photosensitive film excellent in thermal coloration resistance, patternability, and R-to-R adaptability (flexibility in the uncured resin state) for use as the optical waveguide forming material, and provides an optical waveguide produced by using the photosensitive epoxy resin composition or the photosensitive film, and a hybrid flexible printed wiring board for optical and electrical transmission.

The inventors conducted intensive studies to solve the above problem and, as a result, found that the intended object can be achieved by using an epoxy resin having a tri- or higher functional bisphenol-A skeleton as an epoxy resin component.

The present disclosure provides the following features [1] to [10]:

[1] A photosensitive epoxy resin composition for formation of an optical waveguide contains an epoxy resin component and a photo-cationic polymerization initiator, wherein the epoxy resin component includes an epoxy resin having a tri- or higher functional bisphenol-A skeleton.
[2] In the optical waveguide formation photosensitive epoxy resin composition described in Item [1], the epoxy resin component includes a solid semi-aliphatic bifunctional epoxy resin in addition to the epoxy resin having the tri- or higher functional bisphenol-A skeleton.
[3] In the optical waveguide formation photosensitive epoxy resin composition described in Item [2], the solid semi-aliphatic bifunctional epoxy resin is an epoxy resin represented by the following formula (1):

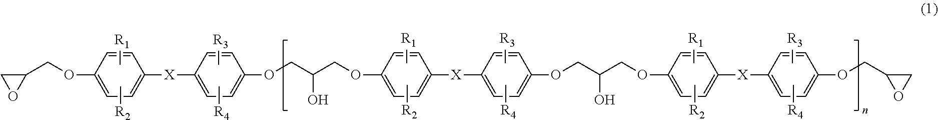

wherein R₁ to R₄, which may be the same or different, are each a hydrogen atom, a methyl group, a chlorine atom, or a bromine atom; X and Y, which may be the same or different, are each a C1 to C15 alkylene group or an alkyleneoxy group; and n is a positive number.
[4] In the optical waveguide formation photosensitive epoxy resin composition described in any of Items [1] to [3], the epoxy resin having the tri- or higher functional bisphenol-A skeleton includes at least one epoxy resin selected from the group consisting of epoxy resins represented by the following formulae (2) and (3):

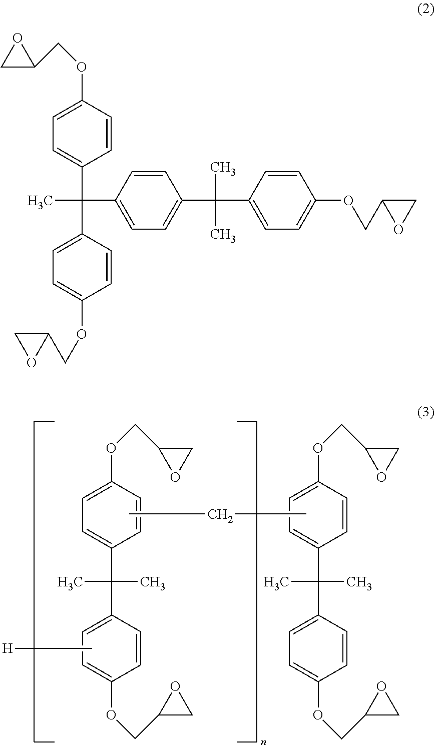

wherein n is a positive number.
[5] In the optical waveguide formation photosensitive epoxy resin composition described in any of Items [1] to [4], wherein the epoxy resin having the tri- or higher functional bisphenol-A skeleton is present in a proportion of 7 to 55 wt. % based on the overall weight of the epoxy resin component.
[6] The optical waveguide formation photosensitive epoxy resin composition described in any of Items [1] to [5] is a core layer forming material for an optical waveguide including a substrate, a cladding layer provided on the substrate, and a core layer provided in a predetermined pattern in the cladding layer for transmission of an optical signal.
[7] The optical waveguide formation photosensitive epoxy resin composition described in any of Items [1] to [5] is a cladding layer forming material for an optical waveguide including a substrate, a cladding layer provided on the substrate, and a core layer provided in a predetermined pattern in the cladding layer for transmission of an optical signal.
[8] A photosensitive film for formation of an optical waveguide is formed from the optical waveguide formation photosensitive epoxy resin composition described in any of Items [1] to [7].
[9] An optical waveguide includes a substrate, a cladding layer provided on the substrate, and a core layer provided in a predetermined pattern in the cladding layer for transmission of an optical signal, wherein at least one selected from the group consisting of the cladding layer and the core layer comprises a cured product of the optical waveguide formation photosensitive epoxy resin composition described in Item [6] or [7] or the optical waveguide formation photosensitive film described in Item [8].
[10] A hybrid flexible printed wiring board for optical and electrical transmission includes the optical waveguide described in Item [9].

According to the present disclosure, the optical waveguide formation photosensitive epoxy resin composition is excellent in thermal coloration resistance, patternability, and R-to-R adaptability (flexibility in the uncured resin state).

### DESCRIPTION OF EMBODIMENT

Next, an embodiment of the present disclosure will be described in detail. However, it should be understood that the present disclosure is not limited to the embodiment.

<<Photosensitive Epoxy Resin Composition for Formation of Optical Waveguide>>

A photosensitive epoxy resin composition for formation of an optical waveguide according to this embodiment (hereinafter sometimes referred to simply as “photosensitive epoxy resin composition”) is prepared by using a specific epoxy resin component and a photo-cationic polymerization initiator. In this embodiment, the term “liquid” or “solid” means that a substance is fluid in a “liquid” state or nonfluid in a “solid” state at an ordinary temperature (25° C.±5° C.). In this embodiment, the term “ordinary temperature” means a temperature range of 25° C.±5° C. as described above.

The ingredients will hereinafter be described in turn.

<Specific Epoxy Resin Component>

Usable as the epoxy resin component are an epoxy resin having three or more epoxy groups on average in its molecule (hereinafter sometimes referred to simply as “polyfunctional epoxy resin”) and a bifunctional epoxy resin having two epoxy groups in its molecule (hereinafter sometimes referred to simply as “bifunctional epoxy resin”). The bifunctional epoxy resin typically has the epoxy groups on opposite terminals of its molecular chain.

A feature of this embodiment is that an epoxy resin having a tri- or higher functional bisphenol-A skeleton is used as the specific epoxy resin component out of the polyfunctional epoxy resin described above. The expression “an epoxy resin having a tri- or higher functional bisphenol-A skeleton” herein, for convenience, means not only an epoxy resin having a higher molecular weight but also an epoxy compound which does not have a high molecular weight comparable to that of an ordinary resin.

In this embodiment, the epoxy resin having the tri- or higher functional bisphenol-A skeleton is used as the epoxy resin component, whereby the photosensitive epoxy resin composition can satisfy the requirements for higher patternability and higher thermal coloration resistance while maintaining the R-to-R adaptability.

That is, it is impossible to impart the photosensitive epoxy resin composition with sufficient photolithography patternability simply by using a common long-chain bifunctional epoxy resin. Therefore, it is essential to additionally use the polyfunctional epoxy resin. Further, various studies reveal that an epoxy resin having a bisphenol-A skeleton improves the thermal coloration resistance as compared with a novolak epoxy resin which is a common polyfunctional epoxy resin.

Examples of the epoxy resin having the tri- or higher functional bisphenol-A skeleton include epoxy resin represented by the following formula (2) and epoxy resin represented by the following formula (3), which may be used alone or in combination. Where the epoxy resin having the tri- or higher functional bisphenol-A skeleton is at least one selected from the group consisting of the epoxy resin of the formula (2) and the epoxy resin of the formula (3), the thermal coloration resistance and the patternability are more excellent.

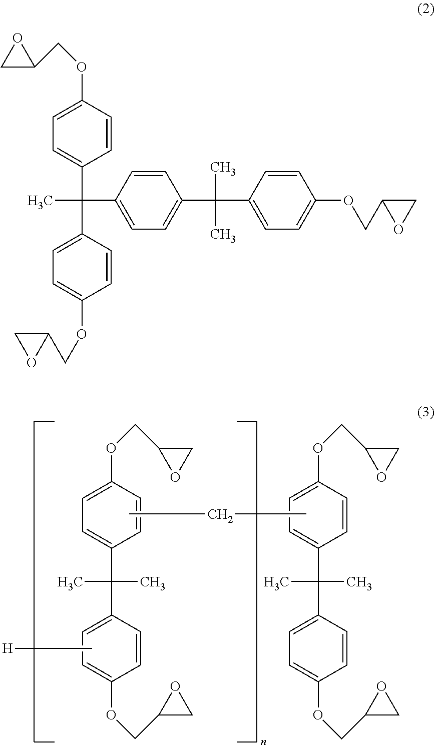

wherein n is a positive number.

In the above formula (3), the repetition number n is a positive number, which is preferably not less than 1, more preferably 1 to 3, on average.

A commercially available product may be used as the epoxy resin represented by the above formula (2), and a specific example thereof is VG3101L manufactured by Printech Co., Ltd. A specific example of the epoxy resin represented by the formula (3) is jER-157S70 manufactured by Mitsubishi Chemical Corporation.

The optical waveguide formation photosensitive epoxy resin composition according to this embodiment may contain an additional polyfunctional epoxy resin other than the epoxy resin having the tri- or higher functional bisphenol-A skeleton. Examples of the additional polyfunctional epoxy resin include trifunctional cresol novolak epoxy resin (e.g., YDCN series manufactured by Nippon Steel & Sumikin Chemical Co., Ltd., and the like), trifunctional aliphatic epoxy resins such as 1,2-epoxy-4-(2-oxiranyl) cyclohexane adduct of 2,2-bis(hydroxymethyl)-1-butanol (e.g., EHPE3150 manufactured by Daicel Corporation) and 1,3,5-trisglycidyl isocyanurate (e.g., TEPIC-S manufactured by Nissan Chemical Industries, Ltd.), phenol novolak epoxy resin (e.g., YDPN series manufactured by Nippon Steel & Sumikin Chemical Co., Ltd., and the like), and specific novolak epoxy resin (e.g., jER-157570 manufactured by Mitsubishi Chemical Corporation, and the like), which may be used alone or in combination.

Of these, the trifunctional aliphatic epoxy resins are preferred, and the 1,2-epoxy-4-(2-oxiranyl) cyclohexane adduct of 2,2-bis(hydroxymethyl)-1-butanol is more preferred.

The content of the polyfunctional epoxy resin is preferably 7 to 55 wt. % based on the total weight of the epoxy resin component from the viewpoint of the patternability.

The content of the epoxy resin having the tri- or higher functional bisphenol-A skeleton out of the polyfunctional epoxy resins described above is preferably 7 to 55 wt. %, more preferably 10 to 50 wt. %, based on the total weight of the epoxy resin component from the viewpoint of the thermal coloration resistance and the patternability.

The content of the additional polyfunctional epoxy resin other than the epoxy resin having the tri- or higher functional bisphenol-A skeleton out of the polyfunctional epoxy resins described above is preferably not greater than wt. % based on the total weight of the epoxy resin component.

The epoxy resin component preferably includes the bifunctional epoxy resin together with the epoxy resin having the tri- or higher functional bisphenol-A skeleton from the viewpoint of the R-to-R adaptability (excellent flexibility in the uncured resin state). Of the bifunctional epoxy resin, a solid semi-aliphatic bifunctional epoxy resin is preferably contained for more excellent R-to-R adaptability.

The solid semi-aliphatic bifunctional epoxy resin is an aromatic ring-containing aliphatic epoxy resin which is in a solid state at an ordinary temperature and has two epoxy functional groups in its molecule.

In general, the flexibility of a resin is attributable to the toughness thereof caused by the entanglement of molecules thereof and the variety of possible conformations of the main chains thereof. For example, a solid resin having a higher softening point and a molecular weight higher than a certain level exhibits higher flexibility in an uncured state. This is attributable to the fact that the higher molecular weight resin has a higher degree of entanglement (interaction) of the main chains thereof. Where the solid resin having a higher softening point is blended in a resin composition, however, a coating varnish of the resin composition having such a formulation is liable to have a higher viscosity, resulting in the need for use of an excess amount of a solvent component. Therefore, the varnish is not suitable for formation of a thicker coating film and is liable to be poorer in patternability.

On the other hand, for example, a resin material having a lower softening point, is expected to have higher flexibility in an uncured state due to the variety of possible conformations of the main chains but without the interaction of the main chains because the main chains are weakly entangled. However, a resin material having a softening point of a middle temperature range between a higher temperature range and a lower temperature range is significantly influenced by the drawbacks of the higher-softening point resin material and the lower-softening point resin material and, therefore, has poorer flexibility. From the viewpoint of the formulation design of the photosensitive epoxy resin composition containing the lower-softening point resin material as the base resin for the uncured-state flexibility, the solid semi-aliphatic bifunctional epoxy resin is used in addition to the epoxy resin having the tri- or higher functional bisphenol-A skeleton, whereby the photosensitive epoxy resin composition can be imparted with higher flexibility in the uncured state.

An example of the solid semi-aliphatic bifunctional epoxy resin is a solid semi-aliphatic bifunctional epoxy resin represented by the following formula (1). Where the solid semi-aliphatic bifunctional epoxy resin is the epoxy resin represented by the following formula (1), the R-to-R adaptability is more excellent.

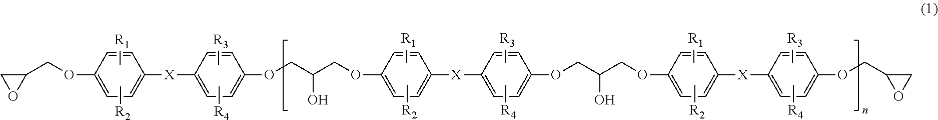

wherein R₁ to R₄, which may be the same or different, are each a hydrogen atom, a methyl group, a chlorine atom or a bromine atom; X and Y, which may be the same or different, are each a C1 to C15 alkylene group or an alkyleneoxy group; and n is a positive number.

The solid semi-aliphatic bifunctional epoxy resin represented by the above formula (1) has a specific molecular chain structure having epoxy groups at opposite terminals of each molecular chain as shown above.

In the above formula (1), as described above, R₁ to R₄ are each hydrogen atom, methyl group, chlorine atom or bromine atom, and X and Y are each C1 to C15 alkylene group or alkyleneoxy group. The repetition number n is a positive number, and is preferably not less than 1 on average. The upper limit of the repetition number n is typically 1,000.

A specific example of the solid semi-aliphatic bifunctional epoxy resin is YX-7180BH40 or the like manufactured by Mitsubishi Chemical Corporation.

The optical waveguide formation photosensitive epoxy resin composition according to this embodiment may contain an additional bifunctional epoxy resin other than the solid semi-aliphatic bifunctional epoxy resin. Examples of the additional bifunctional epoxy resin include bisphenol-A epoxy resin, fluorene epoxy resin, and hydrogenated bisphenol-A epoxy resin, which may be used alone or in combination.

Specific examples of the bisphenol-A epoxy resin include jER1001, jER1002, jER1003, and jER1007 (all manufactured by Mitsubishi Chemical Corporation), and EPIKOTE 1006FS (manufactured by Japan Epoxy Resin Co., Ltd.) Examples of the fluorene epoxy resin include OGSOL PG-100, OGSOL EG-200, OGSOL CG-500, and OGSOL CG-500H (all manufactured by Osaka Gas Chemicals Co., Ltd.). A specific example of the hydrogenated bisphenol-A epoxy resin is YX-8040 (manufactured by Mitsubishi Chemical Corporation).

The proportion of the solid semi-aliphatic bifunctional epoxy resin is preferably not less than 10 wt. %, more preferably 10 to 60 wt. %, still more preferably 15 to 50 wt. %, particularly preferably 20 to 30 wt. %, based on the overall weight of the epoxy resin component from the viewpoint of the R-to-R adaptability. If the proportion of the solid semi-aliphatic bifunctional epoxy resin is excessively small, an uncured film (dried coating film) formed from the photosensitive epoxy resin composition is liable to be poorer in flexibility, suffering from cracking when being handled for the formation of the optical waveguide.

The proportion of the additional bifunctional epoxy resin other than the solid semi-aliphatic bifunctional epoxy resin is preferably not greater than 50 wt. %, more preferably not greater than 40 wt. %, based on the overall weight of the epoxy resin component. Where the proportion of the additional bifunctional epoxy resin is not greater than the aforementioned level, the physical properties of the photosensitive epoxy resin composition are likely to be well balanced.

The weight ratio of the epoxy resin having the tri- or higher functional bisphenol-A skeleton to the bifunctional epoxy resin (the epoxy resin having the tri- or higher functional bisphenol-A skeleton/the bifunctional epoxy resin) is preferably 7/93 to 55/45, more preferably 10/90 to 50/50, in order to ensure the remarkable effects of the present disclosure.

The weight ratio of the epoxy resin having the tri- or higher functional bisphenol-A skeleton to the solid semi-aliphatic bifunctional epoxy resin (the epoxy resin having the tri- or higher functional bisphenol-A skeleton/the solid semi-aliphatic bifunctional epoxy resin) is preferably 15/85 to 90/10, more preferably 20/80 to 85/15, still more preferably 30/70 to 75/25, in order to ensure remarkable effects of the present disclosure.

In this embodiment, the epoxy resin component preferably has the following formulation. The epoxy resin component preferably has a formulation including the epoxy resin having the tri- or higher functional bisphenol-A skeleton and the solid semi-aliphatic bifunctional epoxy resin, and at least one selected from the group consisting of the additional polyfunctional epoxy resin other than the epoxy resin having the tri- or higher functional bisphenol-A skeleton and the additional bifunctional epoxy resin other than the solid semi-aliphatic bifunctional epoxy resin. By thus selectively using the respective epoxy resins in predetermined proportions as the epoxy resin component, the epoxy resin composition can provide a desired refractive index suitable for a core layer or a cladding layer of an optical waveguide.

An epoxy resin component for formation of the core layer is required to have a formulation that ensures a higher refractive index as compared with an epoxy resin component for formation of the cladding layer. Therefore, the formulation of the core layer formation epoxy resin component, i.e., the epoxy resin component that ensures a relatively high refractive index, preferably includes not only the solid semi-aliphatic bifunctional epoxy resin but also the additional bifunctional epoxy resin as the bifunctional epoxy resin.

Examples of the additional bifunctional resin include those as described above. Particularly, the bisphenol-A epoxy resin and the fluorene epoxy resin are preferred, which may be used alone or in combination. Specific examples of the bisphenol-A epoxy resin include jER1001, jER1002, jER1003, and jER1007 (all manufactured by Mitsubishi Chemical Corporation), and EPIKOTE 1006FS (manufactured by Japan Epoxy Resin Co., Ltd.) Specific examples of the fluorene epoxy resin include OGSOL PG-100, OGSOL EG-200, OGSOL CG-500, and OGSOL CG-500H (all manufactured by Osaka Gas Chemicals Co., Ltd.)

On the other hand, the formulation of the cladding layer formation epoxy resin component, i.e., the epoxy resin component that ensures a relatively low refractive index, preferably includes not only the epoxy resin having the tri- or higher functional bisphenol-A skeleton but also the additional polyfunctional epoxy resin as the polyfunctional epoxy resin, and not only the solid semi-aliphatic bifunctional epoxy resin but also the additional bifunctional epoxy resin as the bifunctional epoxy resin.

Examples of the additional polyfunctional epoxy resin include those described above. Particularly, the 1,2-epoxy-4-(2-oxiranyl) cyclohexane adduct of 2,2-bis(hydroxymethyl)-1-butanol (e.g., EHPE3150 manufactured by Daicel Corporation) is preferred.

Examples of the additional bifunctional epoxy resin include those described above. Particularly, the bisphenol-A epoxy resin and the hydrogenated bisphenol-A epoxy resin are preferred. Specific examples of the bisphenol-A epoxy resin include jER1001, jER1002, jER1003, and jER1007 (all manufactured by Mitsubishi Chemical Corporation) and EPIKOTE 1006FS (manufactured by Japan Epoxy Resin Co., Ltd.) A specific example of the hydrogenated bisphenol-A epoxy resin is YX-8040 (manufactured by Mitsubishi Chemical Corporation).

<Photo-Cationic Polymerization Initiator>

In this embodiment, the photo-cationic polymerization initiator (photoacid generator) is used to impart the photosensitive epoxy resin composition with photocurability, e.g., curability by irradiation with ultraviolet radiation.

Examples of the photo-cationic polymerization initiator include triphenylsulfonium hexafluoroantimonate, triphenylsulfonium hexafluorophosphate, p-(phenylthio)phenyldiphenylsulfonium hexafluoroantimonate, p-(phenylthio)phenyldiphenylsulfonium hexafluorophosphate, 4-chlorophenyldiphenylsulfonium hexafluorophosphate, 4-chlorophenyldiphenylsulfonium hexafluoroantimonate, bis[4-(diphenylsulfonio)phenyl]sulfide bishexafluorophosphate, bis[4-(diphenylsulfonio)phenyl]sulfide bishexafluoroantimonate, (2,4-cyclopentadiene-1-yl)[(1-methylethyl)benzene]-Fe-hexafluorophosphate, and diphenyliodonium hexafluoroantimonate, which may be used alone or in combination.

Particularly, a triphenylsulfonium salt hexafluoroantimonate type and a diphenyliodonium salt hexafluoroantimonate type are preferred. Exemplary commercially available products of the photo-cationic polymerization initiator include SP-170 (manufactured by ADEKA Corporation), CPI-101A (manufactured by San-Apro, Ltd.), and WPAG-1056 (manufactured by FUJIFILM Wako Pure Chemical Corporation) as the triphenylsulfonium salt hexafluoroantimonate type, and WPI-116 (manufactured by FUJIFILM Wako Pure Chemical Corporation) as the diphenyliodonium salt hexafluoroantimonate type.

The proportion of the photo-cationic polymerization initiator is preferably 0.1 to 3 parts by weight, more preferably 0.25 to 2 parts by weight, based on 100 parts by weight of the epoxy resin component of the photosensitive epoxy resin composition. If the proportion of the photo-cationic polymerization initiator is excessively small, it will be difficult to impart the photosensitive epoxy resin composition with satisfactory photocurability (UV-curability). If the proportion of the photo-cationic polymerization initiator is excessively great, the photosensitivity tends to be increased, resulting in abnormal shaping in the patterning. Further, required physical properties associated with an initial loss tend to be deteriorated.

As required, the photosensitive epoxy resin composition according to this embodiment may contain additives in addition to the specific epoxy resin component and the photo-cationic polymerization initiator described above. Examples of the additives include adhesiveness imparting agents such as silane coupling agent, titanium coupling agent, olefin oligomer, cycloolefin oligomer and polymer (e.g., norbornene polymer and the like), synthetic rubber, and silicone compound for enhancing the adhesiveness, various antioxidants such as hindered phenol antioxidant and phosphorus-containing antioxidant, leveling agent, and defoaming agent. These additives may be properly blended, as long as the effects of the present disclosure are not impaired. These may be used alone or in combination.

The proportion of the antioxidant is preferably less than 3 parts by weight, particularly preferably not greater than 1 part by weight, based on 100 parts by weight of the epoxy resin component. If the proportion of the antioxidant is excessively great, the required physical properties associated with the initial loss tend to be deteriorated.

The photosensitive epoxy resin composition according to this embodiment can be prepared by mixing the specific epoxy resin component, the photo-cationic polymerization initiator and, as required, any of the additives in the predetermined proportions with stirring. Where the photosensitive epoxy resin composition according to this embodiment is prepared in the form of a coating varnish, the resulting mixture may be dissolved in an organic solvent with heating (e.g., to about 60° C. to about 120° C.) and stirring. The amount of the organic solvent to be used may be properly adjusted, and is preferably set, for example, to 30 to 80 parts by weight, particularly preferably 40 to 70 parts by weight, based on 100 parts by weight of the epoxy resin component of the photosensitive epoxy resin composition. If the amount of the organic solvent to be used is excessively small, the prepared coating varnish tends to have a higher viscosity and hence poorer coatability. If the amount of the organic solvent to be used is excessively great, it will be difficult to form a thicker coating film with the use of the coating varnish.

Examples of the organic solvent to be used for the preparation of the coating varnish include ethyl lactate, methyl ethyl ketone, cyclohexanone, 2-butanone, N,N-dimethylacetamide, diglyme, diethylene glycol methyl ethyl ether, propylene glycol methyl acetate, propylene glycol monomethyl ether, tetramethylfurane, and dimethoxyethane. These organic solvents may be used alone or in combination in a predetermined amount, for example, within the aforementioned range so as to impart the varnish with a viscosity suitable for the coating.

Where the optical waveguide formation photosensitive epoxy resin composition according to this embodiment is used for the formation of the cladding layer or the core layer of the optical waveguide, the cladding layer or the core layer can be formed as having excellent thermal coloration resistance, excellent R-to-R adaptability (excellent flexibility in the uncured resin state), and excellent patternability without changing the conventional production process.

Further, the use of the optical waveguide formation photosensitive epoxy resin composition makes it possible to impart the core layer and/or the cladding layer of the optical waveguide with a desired refractive index. Therefore, the optical waveguide formation photosensitive epoxy resin composition is preferably used as at least one selected from the group consisting of a core layer forming material and a cladding layer forming material for the optical waveguide.

<<Optical Waveguide>>

The photosensitive epoxy resin composition according to this embodiment is used as the cladding layer forming material and the core layer forming material by way of example, which will hereinafter be described.

An optical waveguide according to this embodiment includes, for example, a substrate, a cladding layer (under-cladding layer) provided in a predetermined pattern on the substrate, a core layer provided in a predetermined pattern on the cladding layer for transmitting an optical signal, and another cladding layer (over-cladding layer) provided over the core layer. In the optical waveguide according to this embodiment, the cladding layers are formed from the photosensitive epoxy resin composition described above. Further, the core layer as well as the cladding layers are preferably formed from the photosensitive epoxy resin composition described above. In the optical waveguide according to this embodiment, the cladding layers are required to have a lower refractive index than the core layer.

In this embodiment, the optical waveguide can be produced, for example, through the following process steps. First, a substrate is prepared. Then, a cladding layer forming material (photosensitive varnish) is prepared by dissolving the photosensitive epoxy resin composition of this embodiment in an organic solvent as required, and is applied onto the substrate. After the application of the cladding layer forming material (photosensitive varnish), the organic solvent is removed by heat-drying. Thus, a photosensitive epoxy resin composition film is formed in an uncured state. The varnish coating surface of the uncured photosensitive epoxy resin composition film is irradiated with ultraviolet radiation or the like and, as required, further subjected to a heat treatment, whereby the photosensitive varnish is cured. Thus, an under-cladding layer (lower cladding layer portion) is formed.

Then, a core layer forming material (photosensitive varnish) is prepared, as required, by dissolving the photosensitive epoxy resin composition of this embodiment in an organic solvent, and then applied onto the under-cladding layer to form an uncured core formation layer. After the application of the core layer forming material (photosensitive varnish), the organic solvent may be removed by heat-drying in the same manner as described above, whereby a photosensitive film is formed in an uncured film state. In turn, a photomask for light exposure in a predetermined pattern (optical waveguide pattern) is put on a surface of the uncured core formation layer. Then, the core formation layer is irradiated with light such as ultraviolet radiation via the photomask and, as required, further subjected to a heat treatment. Thereafter, an unexposed portion (uncured portion) of the uncured core formation layer is dissolved away with the use of a developing liquid, whereby a core layer is formed in the predetermined pattern.

Subsequently, the cladding layer forming material (photosensitive varnish) prepared by dissolving the photosensitive epoxy resin composition of this embodiment in the organic solvent is applied over the core layer. Then, the cladding layer forming material is irradiated with light such as ultraviolet radiation and, as required, further subjected to a heat treatment, whereby an over-cladding layer (upper cladding layer portion) is formed. Thus, the intended optical waveguide is produced through these process steps.

It is preferred to form the uncured photosensitive film from the optical waveguide formation photosensitive epoxy resin composition for improvement of the working efficiency in the optical waveguide production process. Further, it is preferred that at least one layer selected from the group consisting of the core layer and the cladding layer of the optical waveguide is formed by curing the optical waveguide formation photosensitive epoxy resin composition or the optical waveguide formation photosensitive film according to this embodiment because the optical waveguide thus produced can be used for information transmission with a lower propagation loss even in a higher temperature environment.

Examples of the substrate include silicon wafer, metal substrate, polymer film, and glass substrate. Examples of the metal substrate include stainless steel plates such as of JIS SUS. Specific examples of the polymer film include polyethylene terephthalate (PET) film, polyethylene naphthalate film, and polyimide film. The substrate typically has a thickness of 10μm to 3 mm.

Specifically, the light irradiation may be irradiation with ultraviolet radiation. Exemplary ultraviolet light sources for the irradiation with the ultraviolet radiation include low-pressure mercury lamp, high-pressure mercury lamp, and ultrahigh-pressure mercury lamp. The dose of the ultraviolet radiation is typically about 10 to about 20,000 mJ/cm², preferably about 100 to about 15,000 mJ/cm², more preferably about 500 to about 10,000 mJ/cm².

After the light exposure by the irradiation with the ultraviolet radiation or the like, the heat treatment may be further performed to complete a photoreaction for the curing. The heat treatment is typically performed at 80° C. to 250° C. for 10 seconds to 2 hours, preferably at 100° C. to 150° C. for 5 minutes to 1 hour.

The photosensitive epoxy resin composition according to this embodiment is preferably used as the core layer forming material, but a photosensitive epoxy resin composition other than the photosensitive epoxy resin composition according to this embodiment may be used as the core layer forming material. The photosensitive epoxy resin composition other than the photosensitive epoxy resin composition according to this embodiment is, for example, an epoxy resin composition containing any of various liquid epoxy resins such as bisphenol-A epoxy resin, bisphenol-F epoxy resin, hydrogenated bisphenol-A epoxy resin, fluorinated epoxy resin, and epoxy-modified silicone resin, and various solid epoxy resins such as solid polyfunctional aliphatic epoxy resin, and any of the aforementioned photo-cationic polymerization initiators. The formulation of the photosensitive epoxy resin composition as the core layer forming material is designed so that the core layer forming material provides a higher refractive index than the cladding layer forming material. For preparation of the core layer forming material to be applied in the form of a varnish, as required, a conventionally known organic solvent may be used in a proper amount so as to impart the varnish with a viscosity suitable for the application of the varnish, and various additives (antioxidant, adhesiveness imparting agent, leveling agent, and UV absorbing agent) may be used in proper amounts as long as the functions of the optical waveguide produced by using the aforementioned cladding layer forming material are not impaired.

Examples of the organic solvent to be used for the preparation of the varnish include ethyl lactate, methyl ethyl ketone, cyclohexanone, 2-butanone, N,N-dimethylacetamide, diglyme, diethylene glycol methyl ethyl ether, propylene glycol methyl acetate, propylene glycol monomethyl ether, tetramethylfurane, and dimethoxyethane as in the aforementioned case. These organic solvents may be used alone or in combination in a proper amount so as to impart the varnish with a viscosity suitable for the application of the varnish.

Exemplary methods for the application of the forming materials for the respective layers on the substrate include coating methods employing a spin coater, a coater, a spiral coater, a bar coater or the like, a screen printing method, a capillary injection method in which the material is injected into a gap formed with the use of spacers by the capillary phenomenon, and a continuous R-to-R coating method employing a coating machine such as a multi-coater. The optical waveguide may be provided in the form of a film optical waveguide by removing the substrate.

Where the optical waveguide produced in the aforementioned manner is used for an optical and electrical transmission hybrid board (opto-electric hybrid board) or a similar product involving optical path deflection, for example, a 45-degree mirror forming process is performed on a surface of the cladding layer of the optical waveguide on the board.

<<Mirror Forming Process>>

A known method such as laser processing method, dicing method or inprint method may be employed for the mirror forming process. Particularly, the laser processing method is preferably used. A laser light source is properly selected according to the laser oscillation wavelength. Examples of the laser light source include various gas lasers such as excimer laser, CO₂ laser, and He—Ne laser. Particularly, ArF excimer laser, KrF excimer laser, F₂ excimer laser or the like is preferably used as the laser light source.

The laser irradiation energy is properly set according to the optical waveguide material. For efficient removal of the resin component, the laser irradiation energy is preferably 100 to 1,000 mJ/cm², particularly preferably 200 to 600 mJ/cm². For improvement of the mirror forming process productivity, the laser irradiation frequency is preferably 10 to 250 Hz, particularly preferably 50 to 200 Hz. The movement speed of the laser irradiation object is properly set according to the optical waveguide material and the design (e.g., angle) of the mirror surface to be formed. The laser wavelength is properly set according to the optical waveguide material, but may be, for example, about 150 nm to about 300 nm, particularly preferably 248 nm.

The optical waveguide thus produced may be used as an optical waveguide, for example, for a hybrid flexible printed wiring board for optical and electrical transmission.

The optical and electrical transmission hybrid flexible printed wiring board (FPC) including the optical waveguide according to this embodiment can be used as a printed wiring board suitable for higher speed and higher capacity information communications even in the higher temperature environment.

### EXAMPLES

Next, the embodiment of the present disclosure will be described by way of examples thereof. However, it should be understood that the present disclosure is not limited to these examples. In the examples, “part(s)” is based on weight, unless otherwise specified.

Before production of optical waveguides, the following ingredients were prepared for preparation of photosensitive varnishes as a cladding layer forming material and a core layer forming material.

[Polyfunctional Epoxy Resin]
VG3101L (manufacture by Printech Co., Ltd.): An epoxy resin having a trifunctional bisphenol-A skeleton represented by the above formula (2)
jER-157570 (manufacture by Mitsubishi Chemical Corporation): An epoxy resin having a trifunctional bisphenol-A skeleton represented by the above formula (3)
YDCN-700-3 (manufacture by Nippon Steel & Sumikin Chemical Co., Ltd.): A cresol novolak epoxy resin
EHPE3150 (manufacture by Daicel Corporation): 1,2-epoxy-4-(2-oxiranyl) cyclohexane adduct (solid) of 2,2-bis(hydroxymethyl)-1-butanol

[Bifunctional Epoxy Resin]
YX-7180BH40 (manufacture by Mitsubishi Chemical Corporation): A solution containing a solid semi-aliphatic bifunctional epoxy resin (represented by the above general formula (1)) dissolved in a mixed solvent (having a cyclohexanone/methyl ethyl ketone mixing weight ratio of 1/1) and having a solid resin content of 40 wt. %
jER-1002 (manufacture by Mitsubishi Chemical Corporation): A solid bisphenol-A epoxy resin
OGSOL PG-100 (manufacture by Osaka Gas Chemicals Co., Ltd.): A fluorene epoxy resin

[Photo-Cationic Polymerization Initiator]
CPI-101A (manufacture by San-Agro, Ltd.): Sulfonium hexafluoroantimonate

[Antioxidant]
Songnox 1010 (manufacture by Kyodo Chemical Co., Ltd.): A hindered phenol antioxidant
HCA (manufacture by Sanko Co., Ltd.): A phosphate antioxidant

### Examples 1 to 5 and Comparative Examples 1 and 2

### <Preparation of Cladding Layer Forming Materials and Core Layer Forming Materials>

Under shaded conditions, ingredients were blended together at 110° C. into complete dissolution according to formulations shown below in Table 1. The proportions of the solid semi-aliphatic bifunctional epoxy resin (YX-7180BH40) are on a solid resin weight basis.

Thereafter, the resulting solutions were each cooled to a room temperature (25° C.), and then filtered under higher-temperature and higher-pressure conditions with the use of a membrane filter having a diameter of 1.0 μm. Thus, photosensitive varnishes were prepared as cladding layer forming materials and core layer forming materials. With the use of the photosensitive varnishes thus prepared, optical waveguides (each having an overall optical waveguide thickness of 75 μm) were produced, which each included an under-cladding layer formed in a predetermined pattern on a back surface of an FPC substrate (a laminate of stainless steel (JIS SUS) and polyimide), a core layer formed in a predetermined pattern on the under-cladding layer, and an over-cladding layer formed over the core layer.

<Production of Resin Layers for Evaluation>

The photosensitive varnishes were each applied onto a silicon wafer by means of a spin coater, and then dried on a hot plate (at 130° C. for 10 minutes) for removal of the organic solvent, whereby uncured layers were formed in an uncured film state. The uncured layers thus formed were each exposed at 4,000 mJ/cm² (cumulative at a wavelength of 365 nm) via a glass mask pattern (pattern width/pattern pitch (L/S)=50 μm/200 μm) by means of a UV irradiation machine (including an ultrahigh-pressure mercury lamp capable of emitting full spectrum light (without a band pass filter)), and then subjected to a post heat treatment (at 140° C. for 10 minutes). Thereafter, the resulting layers were each developed in γ-butyrolactone (at a room temperature (25° C.) for 3 minutes), and rinsed with water. Then, the resulting layers were each dried on a hot plate (at 120° C. for 5 minutes) for removal of water. Thus, resin layers (each having a thickness of 50 μm) were formed in the predetermined pattern.

The resin layers thus formed were each evaluated for thermal coloration resistance, patternability, and uncured-state flexibility through measurement performed by the following methods. The results of the evaluation are shown below in Table 1.

[Thermal Coloration Resistance]

The photosensitive varnishes were each applied by means of a spin coater, whereby uncured layers each having a thickness of 50 μm as measured after heat-drying (at 130° C. for 10 minutes) were formed. The uncured layers thus formed were each exposed at 4,000 mJ/cm² (cumulative at a wavelength of 365 nm) by means of a UV irradiation machine (including an ultrahigh-pressure mercury lamp capable of emitting full spectrum light (without a band pass filter)), and then subjected to a post heat treatment (at 140° C. for 10 minutes). Before and after the resulting cured resin films were heated in an oven at 125° C. for 500 hours, the transmittances of each of the cured resin films were measured at a wavelength of 400 nm by means of a spectrophotometer, and a transmittance change was determined. Based on the determination results, the cured resin films were each evaluated according to the following criteria:

Excellent (∘): The transmittance measured at 400 nm after the heating in the oven at 125° C. was not lower than 90% of the transmittance measured before the heating.
Acceptable (Δ): The transmittance measured at 400 nm after the heating in the oven at 125° C. was not lower than 70% and lower than 90% of the transmittance measured before the heating.
Unacceptable (x): The transmittance measured at 400 nm after the heating in the oven at 125° C. was lower than 70% of the transmittance measured before the heating.

[Patternability]

The patterns of the respective layers formed under the aforementioned conditions were each observed by means of a microscope for checking the appearance thereof. Based on the observation results, the patterns were each evaluated according to the following criteria:

Excellent (∘): The pattern had a rectangular shape.
Acceptable (Δ): The pattern had a rounded portion at its upper portion, but was free from a functional problem.
Unacceptable (x): The pattern had an abnormal shape, and suffered from a functional problem.

[Flexibility of Uncured Product (Uncured Film)]

The photosensitive varnishes were each applied onto a polyethylene terephthalate (PET) substrate, whereby uncured films (amorphous films) each having a thickness of about 80 atm as measured after being heat-dried (at 130° C. for 10 minutes) were each formed. Then, the amorphous film on the PET substrate was rolled around a 4-cm curvature radius roll core and a 2-cm curvature radius roll core, and checked for cracking after being rolled. Based on the checking results, the uncured films were each evaluated according to the following evaluation criteria:

Excellent (∘): The uncured film was free from cracking when being rolled around the 2-cm curvature radius roll core.
Acceptable (Δ): The uncured film was free from cracking when being rolled around the 4-cm curvature radius roll core, but suffered from cracking when being rolled around the 2-cm curvature radius roll core.
Unacceptable (x): The uncured film suffered from cracking when being rolled around the 4-cm curvature radius roll core.

TABLE 1
(parts)

| | | | | | | Comparative Example | |
|---|---|---|---|---|---|---|---|
| | | | | | | 1 | 2 |
| | Example | | | | | Core | Cladding |
| | | | | | 5 | layer | layer |
| | 1 | 2 | 3 | 4 | Cladding layer | forming | forming |
| Category, product name | Core layer forming material | | | | forming material | material | material |
| Polyfunctional epoxy resin | | | | | | | |
| Bisphenol-A skeleton type (VG3101L) | 30 | — | 10 | 50 | 20 | — | — |
| Bisphenol-A skeleton type (jER-157S70) | — | 30 | — | — | — | — | — |
| Cresol novolak type (YTXN-700-3) | — | — | — | — | — | 30 | — |
| Aliphatic type (EHPE3150) | — | — | — | — | 30 | — | 50 |
| Bifunctional epoxy resin | | | | | | | |
| Solid semi-aliphatic type (YX-7180BH40, solid component) | 20 | 20 | 20 | 20 | 30 | 20 | 30 |
| Solid bifunctional type (jER-1002) | 30 | 30 | 50 | 10 | 20 | 30 | 20 |
| Fluorene type (OGSOL PG-100) | 20 | 20 | 20 | 20 | — | 20 | — |
| Photo-cationic polymerization initiator | | | | | | | |
| CPI-101A | 2 | 2 | 2 | 2 | 2 | 2 | 2 |
| Antioxidant | | | | | | | |
| Songnox1010 | 0.5 | 0.5 | 0.5 | 0.5 | 0.5 | 0.5 | 0.5 |
| HCA | 1.5 | 1.5 | 1.5 | 1.5 | 1.5 | 1.5 | 1.5 |
| Organic solvent | | | | | | | |
| Ethyl lactate | 25 | 25 | 25 | 25 | 10 | 25 | 10 |
| Cyclohexanone (contained in YX-7180BH40) | 15 | 15 | 15 | 15 | 22.5 | 15 | 22.5 |
| Methyl ethyl ketone (contained in YX-7180BH40) | 15 | 15 | 15 | 15 | 22.5 | 15 | 22.5 |
| Thermal coloration resistance | ∘ | Δ | ∘ | ∘ | ∘ | x | ∘ |
| Patternability | ∘ | ∘ | Δ | ∘ | ∘ | ∘ | ∘ |
| Uncured-state flexibility | ∘ | ∘ | ∘ | Δ | ∘ | ∘ | x |

The above results indicate that the Examples in which the photosensitive epoxy resin compositions each containing the epoxy resin having the tri- or higher functional bisphenol-A skeleton as the epoxy resin component were used, were excellent in thermal coloration resistance, patternability, and R-to-R adaptability (uncured resin state flexibility). Example 1 in which the photosensitive epoxy resin composition was used as the core layer forming material and Example 5 in which the photosensitive epoxy resin composition was used as the cladding layer forming material were particularly excellent with excellent results in all the evaluation items.

In contrast, Comparative Examples 1 and 2, in which photosensitive epoxy resin compositions not containing the epoxy resin having the tri- or higher functional bisphenol-A skeleton as the epoxy resin component were used, had inferior property evaluation results with at least one of the evaluation items rated as unacceptable (x).

While specific forms of the embodiment of the present disclosure have been shown in the aforementioned examples, the examples are merely illustrative and are not limitative. It is contemplated that various modifications apparent to those skilled in the art could be made within the scope of the disclosure.

The optical waveguide formation photosensitive epoxy resin composition of the present disclosure is useful as a material for formation of a cladding layer or a core layer of an optical waveguide. An optical waveguide produced by using the optical waveguide formation photosensitive epoxy resin composition as the cladding layer forming material or the core layer forming material is used, for example, for a hybrid flexible printed wiring board for optical and electrical transmission, or the like.

1. A photosensitive epoxy resin composition for forming an optical waveguide, comprising:
an epoxy resin component; and
a photo-cationic polymerization initiator;
wherein the epoxy resin component comprises an epoxy resin having a tri- or higher functional bisphenol-A skeleton.

2. The photosensitive epoxy resin composition according to claim 1, wherein the epoxy resin component further comprises a solid semi-aliphatic bifunctional epoxy resin.

3. The photosensitive epoxy resin composition according to claim 2, wherein the solid semi-aliphatic bifunctional epoxy resin comprises an epoxy resin represented by formula (1): 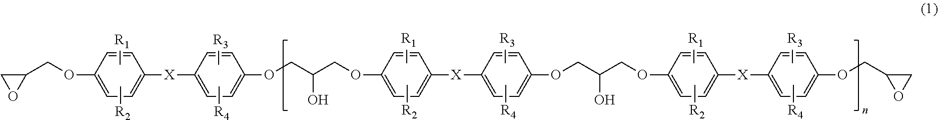
wherein R₁ to R₄, which may be the same or different, are each a hydrogen atom, a methyl group, a chlorine atom, or a bromine atom; X and Y, which may be the same or different, are each a C1 to C15 alkylene group or an alkyleneoxy group; and n is a positive number.

4. The photosensitive epoxy resin composition according to claim 1, wherein the epoxy resin having the tri- or higher functional bisphenol-A skeleton comprises at least one selected from the group consisting of epoxy resins represented by formulae (2) and (3): 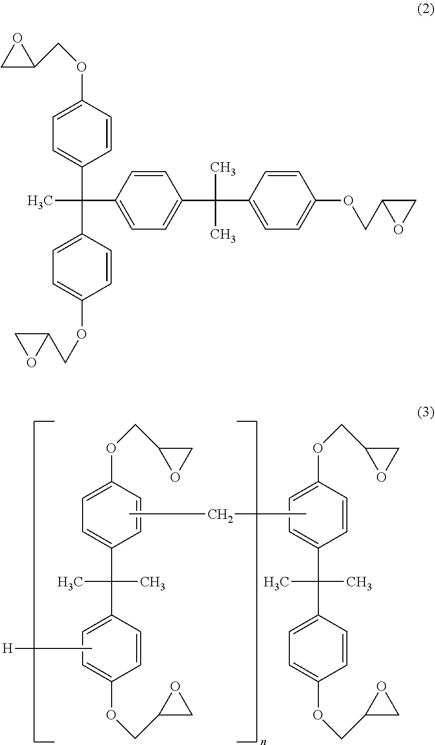
wherein n is a positive number.

5. The photosensitive epoxy resin composition according to claim 1, wherein the epoxy resin having the tri- or higher functional bisphenol-A skeleton is present in a content of 7 to 55 wt. % based on a total weight of the epoxy resin component.

6. The photosensitive epoxy resin composition according to claim 1, which is a core layer forming material for an optical waveguide comprising a substrate, a cladding layer provided on the substrate, and a core layer provided in a predetermined pattern in the cladding layer for transmission of an optical signal.

7. The photosensitive epoxy resin composition according to claim 1, which is a cladding layer forming material for an optical waveguide comprising a substrate, a cladding layer provided on the substrate, and a core layer provided in a predetermined pattern in the cladding layer for transmission of an optical signal.

8. A photosensitive film for forming an optical waveguide, comprising the photosensitive epoxy resin composition according to claim 1.

9. An optical waveguide comprising:
a substrate;
a cladding layer provided on the substrate; and
a core layer provided in a predetermined pattern in the cladding layer for transmission of an optical signal;
wherein at least one selected from the group consisting of the cladding layer and the core layer comprises a cured product of the photosensitive epoxy resin composition according to claim 6.

10. A hybrid flexible printed wiring board for optical and electrical transmission, comprising the optical waveguide according to claim 9.
